(19) United States
(12) Patent Application Publication
(10) Pub. No.: US 2023/0408905 A1
(43) Pub. Date: Dec. 21, 2023

(54) PELLICLE FOR EUV EXPOSURE AND METHOD FOR MANUFACTURING THE SAME

(71) Applicant: Samsung Electronics Co., Ltd., Suwon-si (KR)

(72) Inventors: Mun Ja KIM, Suwon-si (KR); Ki Bong NAM, Suwon-si (KR); Jin Ho YEO, Suwon-si (KR); Byungchul YOO, Suwon-si (KR); Ji Beom YOO, Suwon-si (KR); Changyoung JEONG, Suwon-si (KR)

(73) Assignees: Samsung Electronics Co., Ltd., Suwon-si (KR); RESEARCH & BUSINESS FOUNDATIONSUNGKYUNKWAN UNIVERSITY, Gyeonggi-Do (KR)

(21) Appl. No.: 18/299,301

(22) Filed: Apr. 12, 2023

(30) Foreign Application Priority Data
Jun. 16, 2022 (KR) 10-2022-0073806

(51) Int. Cl. G03F 1/62

(52) U.S. Cl. CPC G03F 1/62

(57) ABSTRACT

A method of manufacturing a pellicle for an extreme ultraviolet exposure includes forming a graphite-containing layer on a catalyst substrate; surface-treating a first surface of the graphite-containing layer to form a first treatment layer; and forming a first passivation layer on the first treatment layer, wherein the forming of the first treatment layer includes removing a C—O—C bond included in the graphite-containing layer through the surface-treating of the first surface.

### CROSS-REFERENCE TO RELATED APPLICATION

This U.S. non-provisional patent application claims priority under 35 U.S.C. § 119 to Korean Patent Application No. 10-2022-0073806, filed on Jun. 16, 2022, in the Korean Intellectual Property Office, the entire contents of which are hereby incorporated by reference.

### BACKGROUND

The inventive concepts relate to pellicles, and more particularly, relate to pellicles for an extreme ultraviolet exposure and methods of manufacturing the same.

A pellicle used in a photomask may be provided in a form of a film on the photomask to protect the photomask from external contaminants (e.g., dust or resist). The pellicle needs to have high transmittance for light used in a photolithography process, and needs to satisfy requirements such as heat dissipation characteristics, strength, durability, and stability. As a critical dimension of a semiconductor device decreases, a wavelength of light used in a photolithography process may be shortened to implement the semiconductor device having the decreased critical dimension.

### SUMMARY

Some example embodiments of the inventive concepts provide a pellicle having high light transmittance and excellent chemical and mechanical durability, and a method of manufacturing the same. Such a pellicle may enable semiconductor devices having decreased critical dimension(s) and thus improved compactness, for example based on the pellicle being configured to enable photolithography processes utilizing light having a relatively short wavelength.

According to some example embodiments of the inventive concepts, a method of manufacturing pellicle for an extreme ultraviolet exposure may include forming a graphite-containing layer on a catalyst substrate, surface-treating a first surface of the graphite-containing layer to form a first treatment layer, and forming a first passivation layer on the first treatment layer, and the forming of the first treatment layer may include removing a C—O—C bond included in the graphite-containing layer through the surface-treating of the first surface.

According to some example embodiments of the inventive concepts, a method of manufacturing pellicle for an extreme ultraviolet exposure may include forming a graphite-containing layer on a catalyst substrate, surface-treating a first surface of the graphite-containing layer to form a first treatment layer, and forming a first passivation layer on the first treatment layer, and the forming of the first treatment layer may include generating at least one of a C═O bond, a C—OH bond, or an O═C—OH bond through the surface-treating of the first surface.

According to some example embodiments of the inventive concepts, a pellicle for an extreme ultraviolet exposure may include a graphite-containing layer, a first treatment layer on the graphite-containing layer, and a first passivation layer on the first treatment layer, the first passivation layer may include element “X”, the first treatment layer may be connected to the first passivation layer by a C—O—X bond, and the element “X” may include at least one of Ti, B, Si, Zr, or Mo.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a cross-sectional view of a pellicle in accordance with some example embodiments.

FIG. 2A is a flowchart of a method of manufacturing the pellicle of FIG. 1 in accordance with some example embodiments.

FIGS. 2B, 2C, and 2D are cross-sectional views for illustrating the method of manufacturing the pellicle according to FIG. 2A in accordance with some example embodiments.

FIG. 3 is a cross-sectional view for illustrating that a pellicle is provided on a photomask according to some example embodiments.

FIGS. 4A, 4B, and 4C are views for illustrating a method of manufacturing a pellicle according to some example embodiments.

FIG. 5 is a cross-sectional view of a pellicle in accordance with some example embodiments.

FIGS. 6A, 6B, 6C, and 6D are cross-sectional views for illustrating a method of manufacturing the pellicle according to FIG. 5 in accordance with some example embodiments.

FIGS. 7A, 7B, and 7C are graphs for illustrating a treatment layer according to some example embodiments and a conventional graphite-containing layer.

FIG. 8 is a graph for illustrating a treatment layer according to some example embodiments and a conventional graphite-containing layer.

FIGS. 9A and 9B are TEM cross-sectional views of a pellicle in accordance with some example embodiments.

FIGS. 10A and 10B are AFM images for illustrating a conventional graphite-containing layer and a treatment layer according to some example embodiments.

FIGS. 11A and 11B are AFM images for illustrating a conventional graphite-containing layer and a treatment layer according to some example embodiments.

FIGS. 12A, 12B, 12C, and 12D are images for illustrating D/G values of a conventional graphite-containing layer and a treatment layer according to some example embodiments.

### DETAILED DESCRIPTION

Hereinafter, to describe the inventive concepts in more detail, some example embodiments according to the inventive concepts will be described in more detail with reference to the accompanying drawings. In this specification, terms indicating an order such as first, and second, are used to distinguish components having the same/similar functions as/to each other, and the first and second may be changed depending on an order in which they are mentioned.

It will be understood that when an element is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%).

Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%).

Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%)).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.).

Hereinafter, pellicles and methods of manufacturing the same according to some example embodiments of the inventive concepts will be described in detail with reference to the drawings.

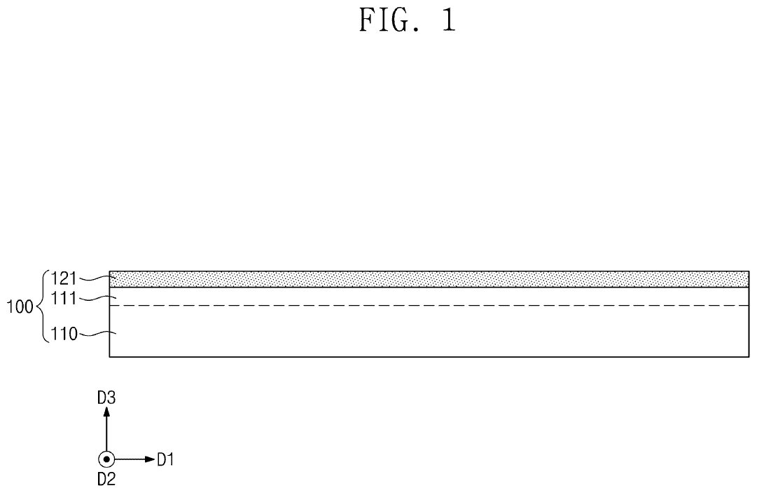

FIG. 1 is a cross-sectional view of a pellicle in accordance with some example embodiments.

Referring to FIG. 1, a pellicle 100 may include a graphite-containing layer 110, a first treatment layer 111 on the graphite-containing layer 110, and a first passivation layer 121 on the first treatment layer 111.

The graphite-containing layer 110 may include graphite. For extreme ultraviolet (EUV) light to be transmitted through the pellicle during an EUV exposure process (e.g., EUV lithography) to at least partially form or manufacture a semiconductor device, the graphite-containing layer 110 may have an appropriate thickness. For example, the graphite-containing layer 110 may be graphite laminated in 40 to 60 layers. For example, the thickness of the graphite-containing layer 110 may be within 25 nm (e.g., 0.01 nm to 25 nm).

The graphite-containing layer 110 may have a plate shape extending along a plane extending in a first direction D1 and a second direction D2. The first direction D1 and the second direction D2 may cross each other. For example, the first direction D1 and the second direction D2 may be horizontal directions orthogonal to each other. Each of the first and second directions D1 and D2 may be understood to extend in parallel with one or more surfaces of one or more of the layers 110, 111, 121 of the pellicle 100.

The first treatment layer 111 may be disposed on the graphite-containing layer 110. The first treatment layer 111 may have greater adsorption (reactivity) to radicals and ions than the graphite-containing layer 110. A content of C—O—C bonds in the first treatment layer 111 may be less than that of the graphite-containing layer 110 (e.g., less than the content of C—O—C bonds in the graphite-containing layer 110). The first treatment layer 111 may have a greater content of C═O bonds, C—OH bonds, or O═C—OH bonds than that of the graphite-containing layer 110 (e.g., greater than the content of C═O bonds, C—OH bonds, or O═C—OH bonds in the graphite-containing layer 110).

The first passivation layer 121 may be disposed on the first treatment layer 111. The first passivation layer 121 may be deposited by atomic layer deposition (ALD). The first passivation layer 121 may protect the pellicle 100 to improve durability and thus to improve performance of the pellicle 100 to support EUV exposure processes using the pellicle 100 in a photomask or in combination with a photomask to at least partially manufacture or form a semiconductor device.

The first treatment layer 111 and the first passivation layer 121 may be connected to each other. A C—O bond of the first treatment layer 111 and an element “X” at a bottom of the first passivation layer 121 (e.g., a side of the first passivation layer 121 that is proximate, adjacent, or the like in relation to the first treatment layer 111, where high transmittance may include a transmittance of 80%-100%, 90%-100%, 95%-100%, 99%-100%, 99.9%-100%, any combination thereof, or the like) may combine with each other to form a C—O—X bond. Accordingly, the first treatment layer 111 and the first passivation layer 121 may be connected by the C—O—X bond. The element “X” may include, for example, at least one of Ti, B, Si, Zr, or Mo. The first passivation layer 121 may include, for example, at least one of TiN, BS, BN, SiC, Zr, or Mo.

For high transmittance of the pellicle 100 (e.g., high transmittance of EUV light through the layers 110, 111, 121 of the pellicle 100), a thickness of the first passivation layer 121 (e.g., in the third direction D3) may be less than 3 nm (e.g., 0.01 nm to 3 nm). The first passivation layer 121 may be a hydrogen-resistant amorphous layer.

The pellicle 100 according to some example embodiments may include the first treatment layer 111 on the graphite-containing layer 110, and the first treatment layer 111 may have the greater content of the C═O bonds, the C—OH bonds, or than O═C—OH bonds than that of graphite-containing layer 110, and thus the absorption (reactivity) of the first treatment layer 111 to the radicals and ions may be greater than that of the graphite-containing layer 110. Therefore, forming the first passivation layer 121 on the first treatment layer 111 by atomic layer deposition (ALD) may be easier than directly forming the first passivation layer 121 on the graphite-containing layer 110. Accordingly, the thinner first passivation layer 121 may be formed more efficiently and uniformly, thereby improving efficiency and ease of manufacture of a pellicle 100 which is configured to enable high transmittance (e.g., 80%-100%, 90%-100%, 95%-100%, 99%-100%, or the like) of EUV light to thus improve the performance of the pellicle 100 in enabling EUV exposure processes to be performed using the pellicle 100 in a photomask and/or in combination with a photomask to manufacture semiconductor devices having a reduced critical dimension and thus a smaller size (e.g., semiconductor devices having improved compactness). Accordingly, based on pellicle 100 including the first treatment layer 111 on the graphite-containing layer 110 where the first treatment layer is connected to the first passivation layer by a C—O—X bond, and where the element “X” includes at least one of Ti, B, Si, Zr, or Mo, and/or where the first treatment layer 111 is formed based on removing a C—O—C bond included in the graphite-containing layer 110 through a surface-treating of a first surface of the graphite-containing layer 110, the pellicle 100 may be configured to enable improved efficiency of manufacture of smaller semiconductor devices based on using the pellicle 100 in a photomask and/or in combination with a photomask to at least partially manufacture (e.g., form) the smaller (e.g., more compact) semiconductor devices through EUV exposure process (e.g., EUV lithography).

The pellicle 100 may include the first passivation layer 121 to have higher (e.g., greater) durability, tensile strength, and EUV resistance. In addition, as the thin first passivation layer 121 may be deposited, the transmittance may be high, and thus efficiency of an extreme ultraviolet (EUV) exposure process may be increased based on the pellicle 100 including the first passivation layer 121 which is connected to the first treatment layer 111 as described herein. Accordingly, due to the pellicle 100 having improved durability, tensile strength and EUV resistance due to including the first passivation layer 121 according to some example embodiments, the pellicle 100 may enable improved efficiency of manufacturing smaller (e.g., more compact) semiconductor devices due to using the pellicle 100 in an EUV exposure process (e.g., EUV lithography).

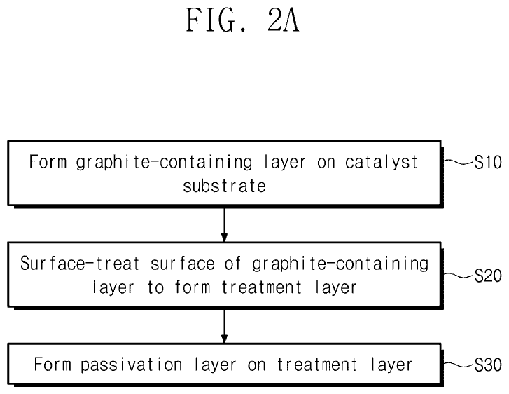

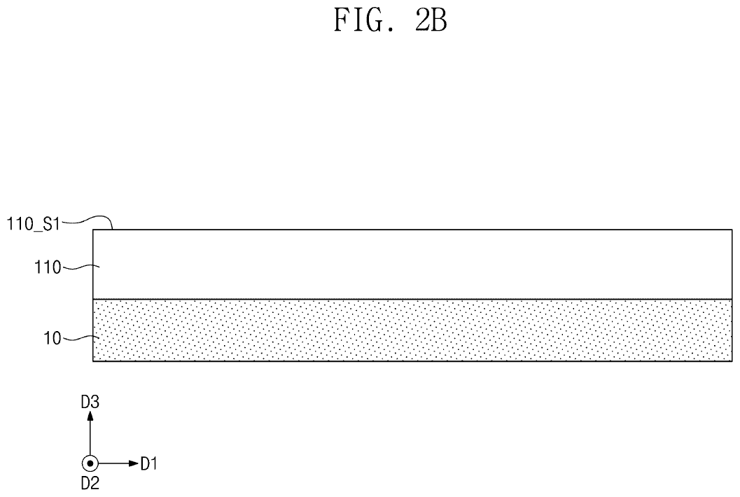

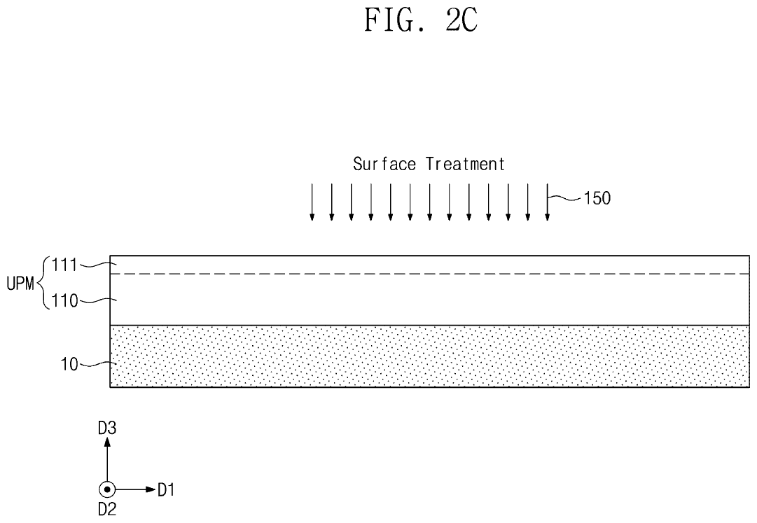

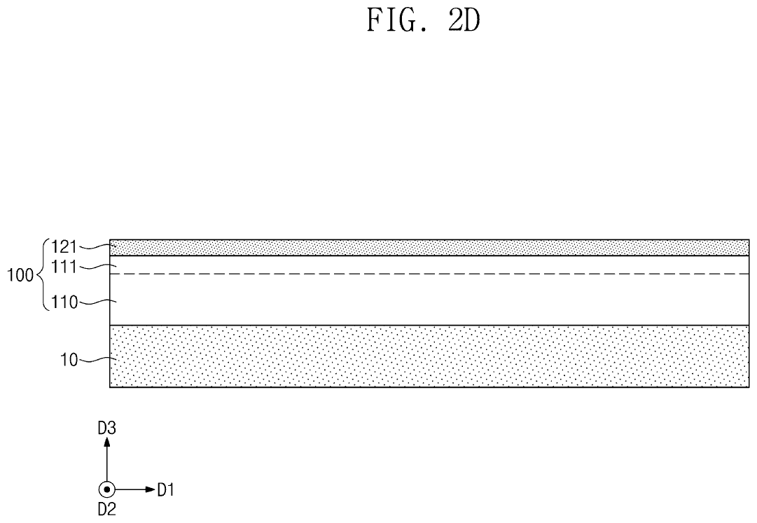

FIG. 2A is a flowchart of a method of manufacturing the pellicle of FIG. 1 in accordance with some example embodiments.

FIGS. 2B, 2C, and 2D are cross-sectional views for illustrating the method of manufacturing the pellicle according to FIG. 2A in accordance with some example embodiments.

Referring to FIGS. 2A and 2B, a method of manufacturing a pellicle according to some example embodiments may include forming a graphite-containing layer 110 on a catalyst substrate 10 in S10.

The catalyst substrate 10 may include a metal or a metal compound. The catalyst substrate 10 may include at least one of copper (Cu), chromium (Cr), nickel (Ni), aluminum (Al), or other metals, or alloys thereof. In some example embodiments, the catalyst substrate 10 may include silicon (Si). For example, the catalyst substrate 10 may include a silicon wafer.

A deposition process such as a chemical vapor deposition (CVD) process or an atomic layer deposition (ALD) process may be performed on the catalyst substrate 10 to form the graphite-containing layer 110. The graphite-containing layer 110 may include graphite.

The graphite-containing layer 110 formed on the catalyst substrate 10 may include a first surface 110_S1. The first surface 110_S1 may be disposed on the uppermost end of the graphite-containing layer 110. In some example embodiments, the first and second directions D1 and D2 may be understood to extend in parallel with the first surface 110_S1 and differently from each other (e.g., perpendicular to each other), while the third direction D3 may be understood to extend perpendicular to the first surface 110_S1 and thus perpendicular to both the first and second directions D1 and D2.

Referring to FIGS. 2A, 2B and 2C, a first treatment layer 111 may be formed on the graphite-containing layer 110 formed on the catalyst substrate 10 in S20. The first surface 110_S1 of the graphite-containing layer 110 formed on the catalyst substrate 10 may be surface-treated 150 (e.g., a surface treatment of the first surface 110_S1 may be performed) to form the first treatment layer 111 in S20. As shown, the first treatment layer 111 formed through such surface-treating of the first surface 110_S1 may result in the first treatment layer 111 being formed from a portion of the graphite-containing layer 110 that is proximate (e.g., adjacent) to the first surface 110_S1, such that the first treatment layer 111 and the graphite-containing layer 110 may be separate portions of a single, unitary piece of material UPM may have different material compositions in different portions (where said different portions of the unitary piece of material having different material compositions define the separate graphite-containing layer 110 and the separate first treatment layer 111 within the unitary piece of material).

When the first treatment layer 111 is formed through the surface treatment 150 of the first surface 110_S1, a C—O—C bond included in the graphite-containing layer 110 (e.g., a C—O—C bond include in a portion of the graphite-containing layer 110 that is proximate to the first surface 110_S1) may be removed. When the first treatment layer 111 is formed through the surface treatment 150 (e.g., formed through the surface-treating) of the first surface 110_S1, at least one of a C═O bond, a C—OH bond, or an O═C—OH bond may be generated.

The surface treatment 150 (e.g., surface-treating) of the first surface 110_S1 may include exposing the first surface 110_S1 of the graphite-containing layer 110 to oxygen plasma. The exposure to the oxygen plasma may be to expose the first surface 110_S1 to 50 sccm of oxygen gas at 10 W for 30 seconds to 1 minute and 30 seconds. In some example embodiments, the surface treatment 150 (e.g., the surface-treating) may include exposing the first surface 110_S1 to Ar, N₂, or He plasma. In some example embodiments, the surface treatment 150 may include exposing the first surface 110_S1 to atmospheric plasma.

In some example embodiments, the surface treatment 150 (e.g., the surface-treating) of the first surface 110_S1 may include combining a —OH group or a molecule having the —OH group with the first surface 110_S1 using a self-assembly-molecule technology such as Langmuir-Blodgett (LB). In some example embodiments, the surface treatment 150 of the first surface 110_S1 may include combining a —OH group or a molecule having the —OH group with the first surface 110_S1 by an octadecyltrichlorosilane (OTS)-based self-assembled monolayer forming process.

In some example embodiments, the surface treatment 150 of the first surface 110_S1 may include pressure printing a —OH group or a molecule having the —OH group on the first surface 110_S1 under high temperature and high pressure. In some example embodiments, the surface treatment 150 of the first surface 110_S1 may be performed using an inkjet printing technique.

By the above-described surface treatment 150 (e.g., surface-treating of the first surface 110_S1), the first treatment layer 111 may be formed such that a surface roughness (RMS) of the first treatment layer 111 is greater than 3.46 nm and less than 32.3 nm. By the above-described surface treatment 150, the first treatment layer 111 may be formed such that a D/G ratio of the first treatment layer 111 is 0.1 or more and less than 0.2 (e.g., between 0.1 and 0.2).

Referring to FIG. 2D, a first passivation layer 121 may be formed on the first treatment layer 111 in S30. The first passivation layer 121 may be formed by atomic layer deposition (ALD). A pellicle 100 including the graphite-containing layer 110, the first treatment layer 111, and the first passivation layer 121 may be formed on the catalyst substrate 10.

The first passivation layer 121 may include an element “X”. At least one of a C═O bond, a C—OH bond, or an O═C—OH bond of the first treatment layer 111 and the element “X” of the first passivation layer 121 may form a C—O—X bond. The first treatment layer 111 and the first passivation layer 121 may be connected by the C—O—X bond. The element “X” may include at least one of Ti, B, Si, Zr, or Mo. The first passivation layer 121 may be formed to include at least one of TiN, BC, BN, SiC, Zr, or Mo.

The pellicle 100 including the graphite-containing layer 110, the first treatment layer 111, and the first passivation layer 121 may be separated from the catalyst substrate 10 to obtain the pellicle 100 of FIG. 1.

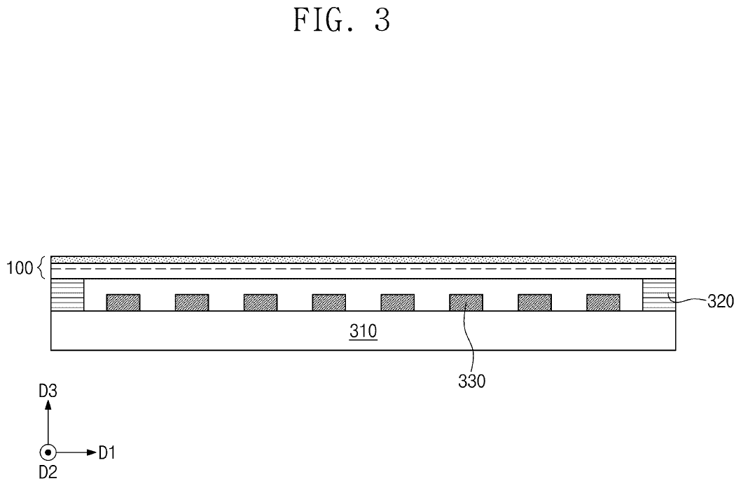

FIG. 3 is a cross-sectional view for illustrating that a pellicle is provided on a photomask according to some example embodiments.

Referring to FIG. 3, a photomask pattern 330 may be formed on a photomask substrate 310. The photomask substrate 310 and the photomask pattern 330 may be components used in an exposure process. The photomask substrate 310 and a pellicle 100 may overlap in a third direction D3. A frame 320 may be interposed between the photomask substrate 310 and the pellicle 100. The frame 320 may separate the photomask substrate 310 from the pellicle 100. As the pellicle 100 is provided on the photomask substrate 310 and the photomask pattern 330, the photomask substrate 310 and the photomask pattern 330 may be protected from (e.g., isolated from exposure to) the atmosphere or any particles (e.g., isolated therefrom by the pellicle 100 alone or in combination with the frame 320).

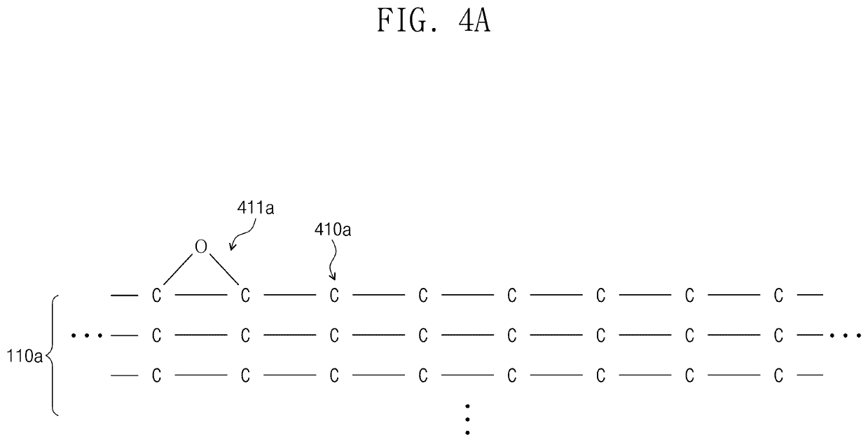

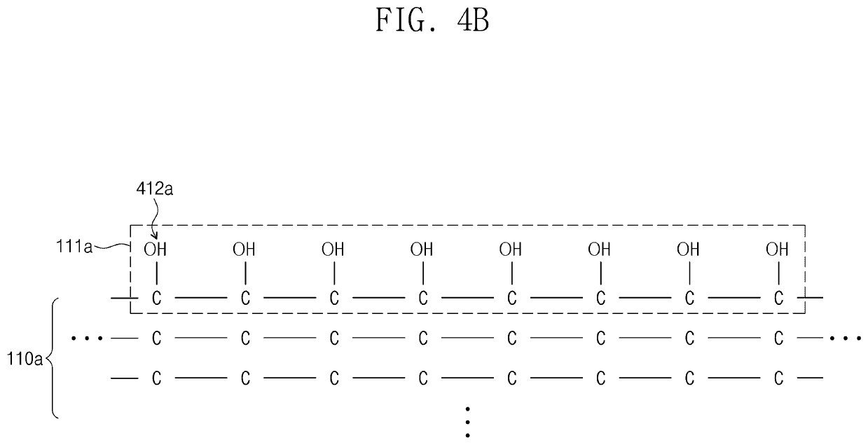

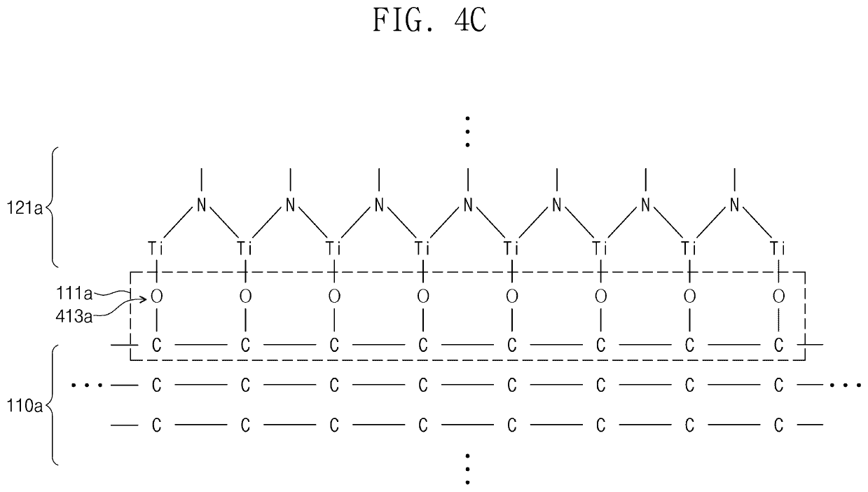

FIGS. 4A, 4B, and 4C are views for illustrating a method of manufacturing a pellicle according to some example embodiments.

Referring to 4A, 4B, and 4C, an example of the surface treatment 150 (e.g., the surface-treating of the first surface 110_S1 of a graphite-containing layer 110) for forming the first treatment layer 111 of the pellicle is shown.

Referring to FIG. 4A, a graphite-containing layer 110a before the surface treatment 150 is provided. The graphite-containing layer 110a may include carbon 410a and oxygen. The graphite-containing layer 110a may react with oxygen in the atmosphere to contain oxygen while being exposed to the atmosphere even before the surface treatment 150. The graphite-containing layer 110a may contain 0.45% to 0.75% oxygen atoms even before the surface treatment 150. Accordingly, the graphite-containing layer 110a may contain C—O—C bonds 411a before (e.g., prior to) the surface treatment 150.

Referring to FIG. 4B, a first treatment layer 111a may be formed by the surface treatment 150 of the graphite-containing layer 110a. A portion of the graphite-containing layer 110a whose molecular structure is converted by the surface treatment 150 may be defined as the first treatment layer 111a. The C—O—C bond 411a included in the graphite-containing layer may be removed through the surface treatment 150, and an —OH group 412a may be formed on the graphite-containing layer 110a. The first treatment layer 111a may include carbon and the —OH group 412a. The first treatment layer 111a may have more C—O bonds than the graphite-containing layer 110a. Although not shown, in some example embodiments, a C═O bond or an O═C—OH bond may be formed through the surface treatment 150.

In some example embodiments, the —OH group 412a may be formed through the surface treatment 150 that includes exposing the graphite-containing layer 110a to oxygen plasma. In some example embodiments, the —OH group 412a may be formed on the graphite-containing layer 110a by oxygen plasma and H₂O, H₂, N₂ or O₂ in the atmosphere.

The first treatment layer 111a formed by the surface treatment 150 on the hydrophobic graphite-containing layer 110a may be hydrophilic, and the first treatment layer 111a may contain a large amount of the —OH groups 412a, and thus the first treatment layer 111a may be hydrophilic. Reactivity with radicals and ions of the first treatment layer 111a may be greater than that of the graphite-containing layer 110a.

Referring to FIG. 4C, a first passivation layer 121a may be formed on the first treatment layer 111a. The first treatment layer 111a may be deposited through ALD. The first passivation layer 121a may include an element “X”. In some example embodiments, the element “X” may be Ti as shown.

The —OH group 412a of the first treatment layer 111a may react with a derivative including the element “X” to form a first passivation layer 121a. In some example embodiments, the oxygen 413a of the first treatment layer 111a may be combined with the element “X” of the first passivation layer 121a. The first passivation layer 121a may be connected by a C—O—X bond.

In some example embodiments, the first passivation layer 121a may be formed to include TiN. In some example embodiments, the —OH group 412a of the first treatment layer 111a may react with TiCl₄ serving as a derivative, and the following reaction may occur.

R—OH+TiCl₄→R—O-TiCl₃+HCl

Then, when R—I is injected as an activator (where R may be any organic compound, including for example any C1-C20 alkane), the following reaction may occur.

R—O—TiCl₃+RI→R—O-TiI₃+HI

Then, when NH3 is injected, the following reaction may occur.

R—O—TiI₃+NH3→R—O-TiN+3HI

Through the above-described reaction, the first passivation layer 121a including TiN may be formed on the first treatment layer 111a.

Although not shown, the first passivation layer 121a including one of TiN, BC, BN, SiC, Zr, or Mo may be formed on the first treatment layer 111a through a similar reaction.

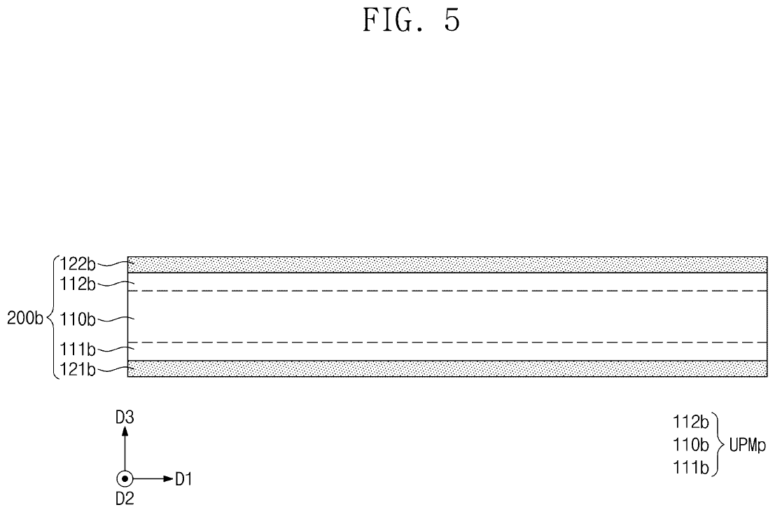

FIG. 5 is a cross-sectional view of a pellicle 200b in accordance with some example embodiments.

Referring to FIG. 5, a pellicle 200b may include a plurality of treatment layers 111b and 112b and a plurality of passivation layers 121b and 122b. A first treatment layer 111b may be disposed on a first passivation layer 121b. A graphite-containing layer 110b may be disposed on the first treatment layer 111b. A second treatment layer 112b may be disposed on the graphite-containing layer 110b. The first and second treatment layers 111b and 112b and the graphite-containing layer 110b may be separate portions of a single, unitary piece of material UPMb. A second passivation layer 122b may be disposed on the second treatment layer 112b. The first passivation layer 121b and the second passivation layer 122b may include different materials. The first passivation layer 121b, the first treatment layer 111b, the graphite-containing layer 110b, the second treatment layer 112b, and the second passivation layer 122b may be stacked in a third direction D3.

The pellicle 200b may include the plurality of passivation layers 121b and 122b, and thus durability thereof may be enhanced, enabling improved performance of the pellicle 200b in enabling EUV exposure processes using the pellicle 200b in a photomask or in combination with a photomask to at least partially manufacture or form a semiconductor device, thereby enabling improved efficiency of manufacture of smaller, more compact semiconductor devices due to forming or manufacturing the semiconductor devices through EUV exposure processes.

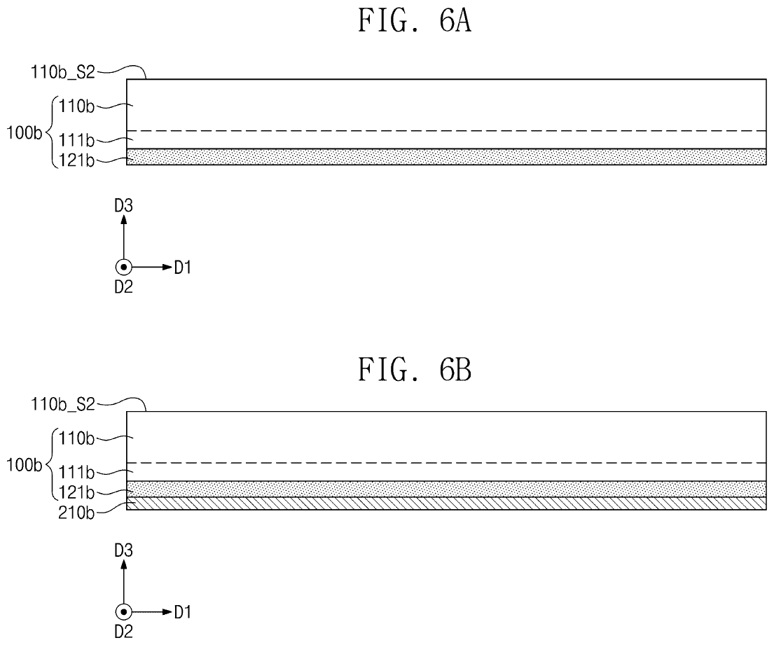

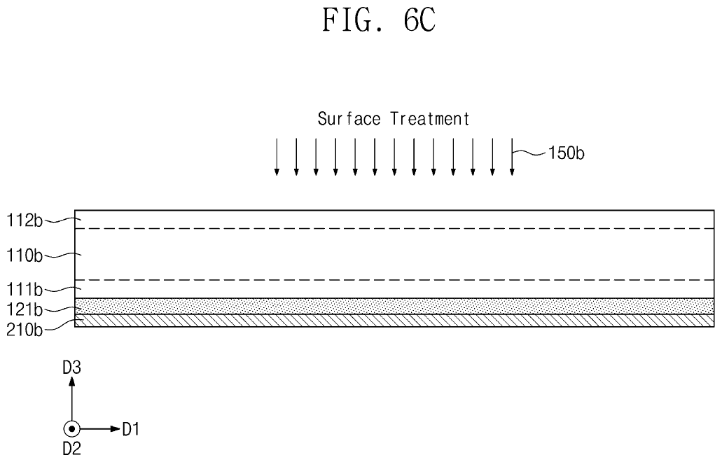

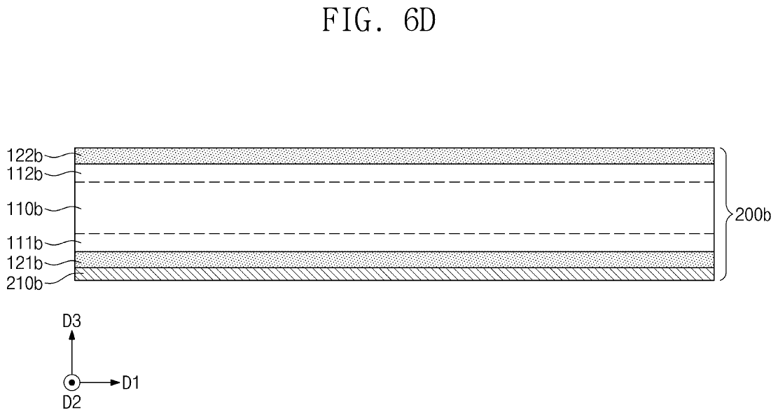

FIGS. 6A, 6B, 6C, and 6D are cross-sectional views for illustrating a method of manufacturing the pellicle 200b according to FIG. 5 in accordance with some example embodiments.

Referring to FIG. 6A, a pellicle 100b including the first passivation layer 121b, the first treatment layer 111b, and the graphite-containing layer 110b may be provided. The graphite-containing layer 110b may include a second surface 110b_S2. The second surface 110b_S2 may be a surface of the graphite-containing layer 110b that is not connected to the first treatment layer 111b. The pellicle 100b may be manufactured similarly to the manufacturing method of FIGS. 2A to 2D.

Referring to FIG. 6B, the first passivation layer 121b may be covered with a sublimation material 210b. The sublimation material may include, for example, any one of camphor, naphthalene, or menthol. The first passivation layer 121b may be covered with the sublimation material 210b, and thus the first treatment layer 111b and the first passivation layer 121b may not be exposed to the outside. The second surface 110b_S2 of the graphite-containing layer 110b may be exposed to the outside.

Referring to FIGS. 6B and 6C, when the first passivation layer 121b is covered with the sublimation material 210b, the second surface 110b_S2 of the graphite-containing layer 110b may be surface-treated 150b.

Similar to FIGS. 2B and 2C, the second treatment layer 112b may be formed by the surface treatment 150b (e.g., formed through the surface-treating of the second surface 110b_S2). During the surface treatment 150b, the first treatment layer 111b and the first passivation layer 121b may not be exposed to the surface treatment 150b due to the sublimation material 210b. The first treatment layer 111b and the first passivation layer 121b may not react during the surface treatment 150b.

Referring to FIG. 6D, similarly to FIGS. 2C and 2D, the second passivation layer 122b may be formed on the second treatment layer 112b. When the sublimation material 210b is sublimed after the second passivation layer 122b is formed, the pellicle 200b of FIG. 5 may be formed.

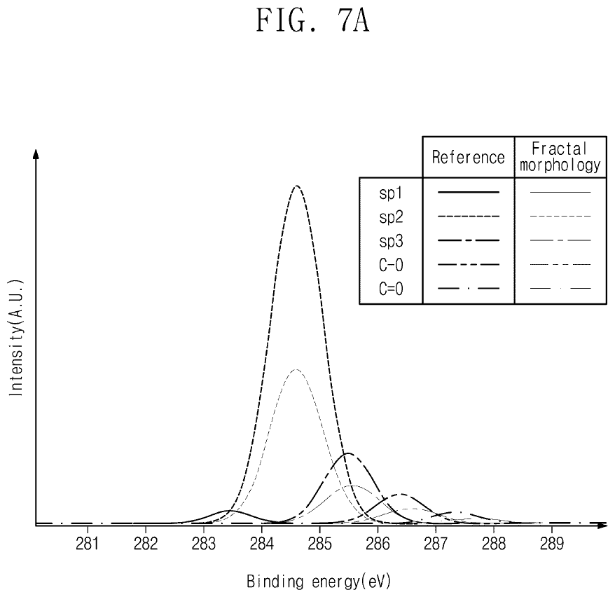

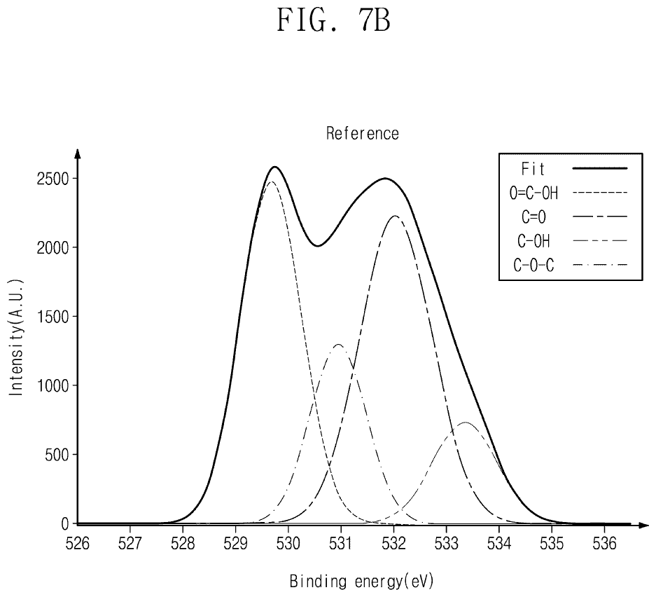

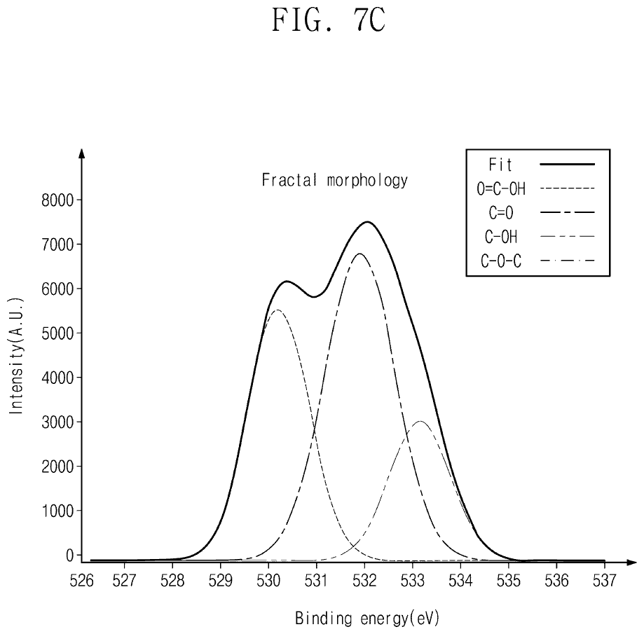

FIGS. 7A, 7B, and 7C are graphs for illustrating a treatment layer according to some example embodiments and a conventional graphite-containing layer.

Referring to FIG. 7A, a value of the conventional graphite-containing layer (Reference) and a value of the first treatment layer 111 (Fractal morphology) formed by surface treatment 150 of the graphite-containing layer 110 in relation to x-ray photoelectron spectroscopy (XPS)-intensity are illustrated as a graph.

A y-axis of the graph is an intensity (shown in arbitrary units A.U.), and an x-axis of the graph is a magnitude of a binding energy (e.g., in units of eV). It may be interpreted that the higher (e.g., greater) the intensity, the more corresponding bonds.

In terms of an intensity value (e.g., in arbitrary units A.U.) of an sp1 bond, an intensity value of an sp1 bond of the conventional graphite-containing layer is greater than an intensity value of an sp1 bond of the first treatment layer 111. Through this, it may be interpreted that the conventional graphite-containing layer has more sp1 bonds than the first treatment layer 111.

In terms of an intensity value of an sp2 bond, an intensity value of an sp2 bond of the conventional graphite-containing layer is greater than an intensity value of an sp2 bond of the first treatment layer 111. Through this, it may be interpreted that the conventional graphite-containing layer has more sp2 bonds than the first treatment layer 111.

In terms of an intensity value of an sp3 bond, an intensity value of an sp3 bond of the conventional graphite-containing layer is greater than an intensity value of an sp3 bond of the first treatment layer 111. Through this, it may be interpreted that the conventional graphite-containing layer has more sp3 bonds than the first treatment layer 111.

In terms of an intensity value of a C—O bond, an intensity value of a C—O bond of the conventional graphite-containing layer 110 is greater than an intensity value of a C—O bond of the first treatment layer 111. Through this, it may be interpreted that the conventional graphite-containing layer has more C—O bonds than the first treatment layer 111.

In terms of an intensity value of a C═O bond, an intensity value of a C═O bond of the conventional graphite-containing layer 110 is greater than an intensity value of a C═O bond of the first treatment layer 111. Through this, it may be interpreted that the conventional graphite-containing layer has more C═O bonds than the first treatment layer 111.

Referring to FIGS. 7B and 7C, the O═C—OH, C═O, C═OH, C—O—C bonds of the conventional graphite-containing layer and their fitting values are graphically shown in FIG. 7B, and the O═C—OH, C═O, C═OH, C—O—C bonds of the first treatment layer 111 and their fitting values are graphically shown in FIG. 7C.

The conventional graphite-containing layer may have more C—O—C bonds than C—OH bonds. The conventional graphite-containing layer may have O═C—OH bonds, C═O bonds, C—O—C bonds, and C—OH bonds in order of quantity.

In the case of the first treatment layer 111, C—O—C bonds may be reduced depending on the surface treatment, and C—O—C bonds may not be formed. The first treatment layer 111 may have C═O bonds, O═C—OH bonds, C═O bonds, C—OH bonds, and C—O—C bonds in order of quantity.

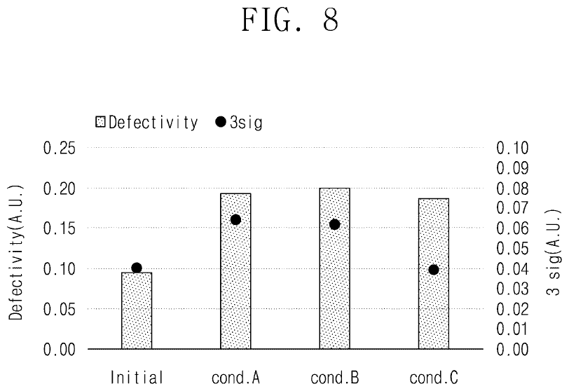

FIG. 8 is a graph for illustrating the treatment layer 111 according to some example embodiments and the conventional graphite-containing layer.

A value of the conventional graphite-containing layer is indicated by Initial, and values of the first treatment layer 111 are indicated by cond.A, cond.B, and cond.C, respectively.

The cond.A is a value of some example embodiments when the surface treatment 150 is exposed to oxygen plasma for 30 seconds, the cond.B is a value of some example embodiments when the surface treatment 150 is exposed to oxygen plasma for 60 seconds, and the cond. C is a value of some example embodiments when surface treatment 150 is exposed to oxygen plasma for 90 seconds.

A D/G ratio is shown as a defectivity value, and the defectivity (defectivity at area) per 100×100 μm² of area of the respective first surface of the conventional graphite-containing layer (Initial) and of the first treatment layer 111 (cond.A, cond.B, and cond.C) shows a scale as 3 sig. Comparison of Initial and cond.A, cond.B, and cond.C is as follows.

TABLE 1

| 100 × 100 μm² | Initial | cond. A | cond. B | cond. C |
|---|---|---|---|---|
| defectivity | 0.09 | 0.19 | 0.20 | 0.19 |
| 3 sig | 0.04 | 0.06 | 0.06 | 0.04 |

Summarizing result values of cond.A, cond.B, and cond.C, a defectivity value of the first treatment layer 111 may be greater than that of the conventional graphite-containing layer 110, and the defectivity value of 0.2 and 0.19 may be obtained.

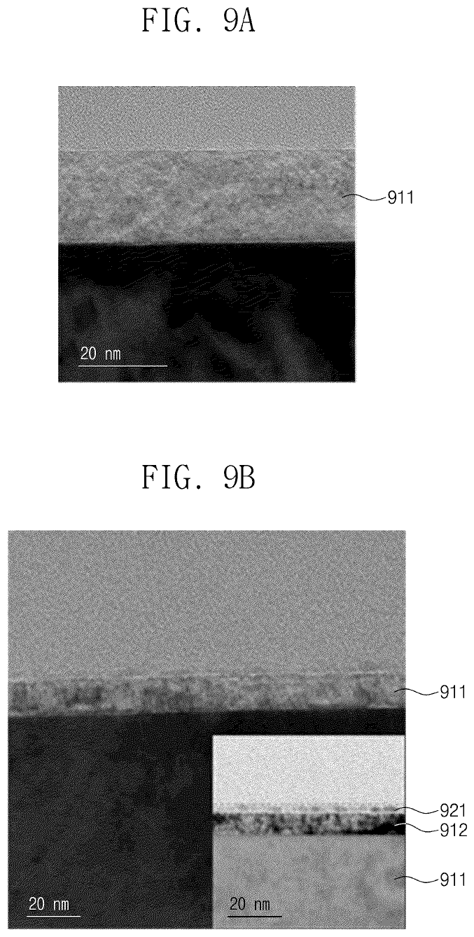

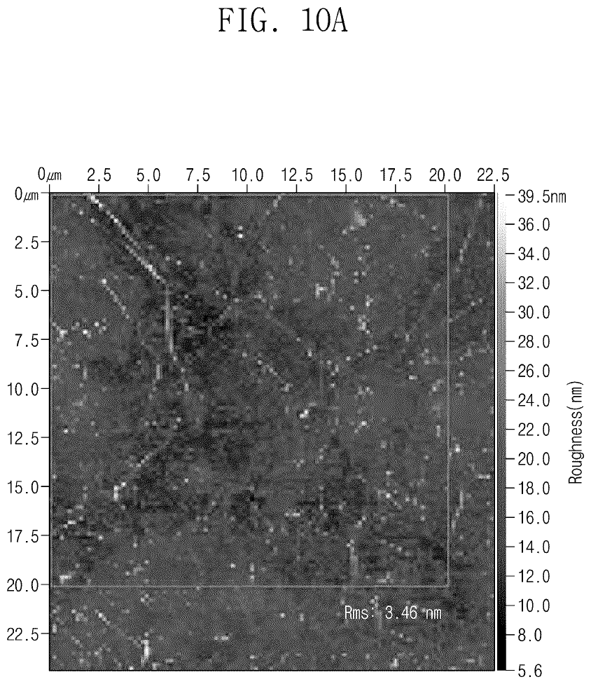

FIGS. 9A and 9B are TEM cross-sectional views of a pellicle in accordance with some example embodiments.

Referring to FIGS. 9A and 9B, in a pellicle according to some example embodiments, it is confirmed that a treatment layer 912 is formed on a surface-treated graphite-containing layer 911 and a first passivation layer 921 is formed on the treatment layer 912.

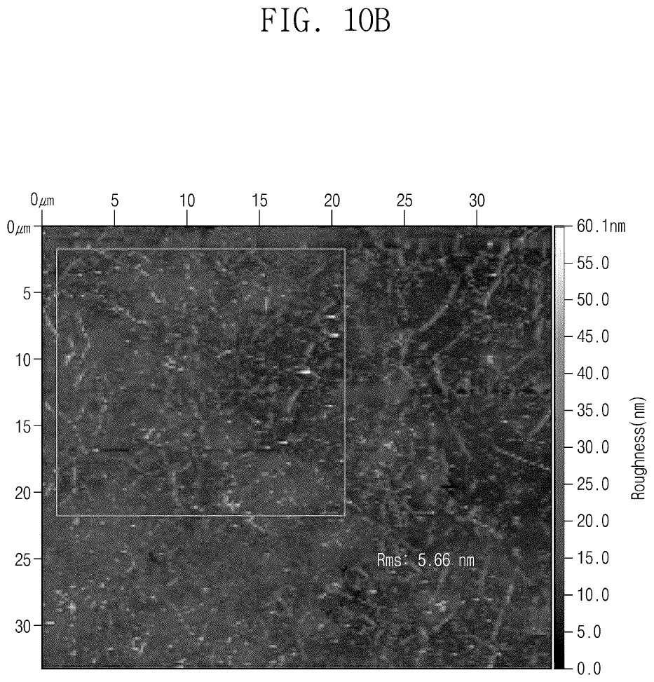

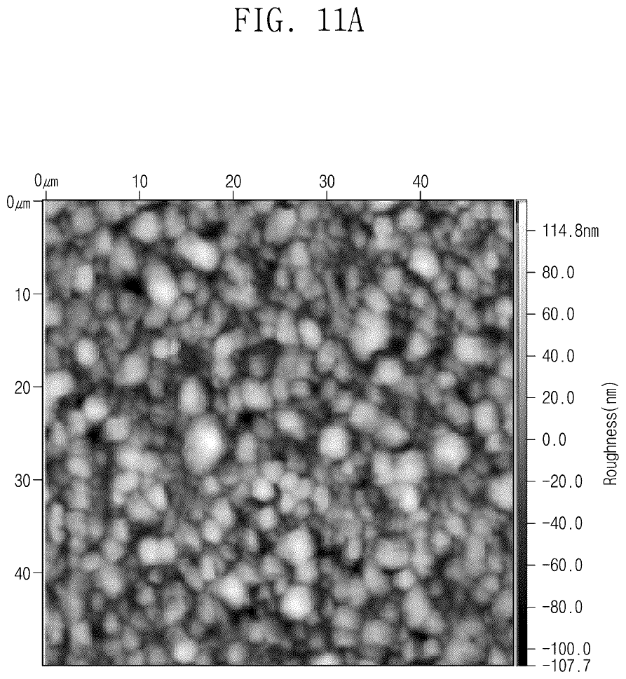

FIGS. 10A and 10B are AFM images for illustrating a conventional graphite-containing layer and a treatment layer according to some example embodiments.

FIGS. 10A and 10B may show surface roughness of the conventional graphite-containing layer and the treatment layer 111, respectively, according to some example embodiments.

Referring to FIG. 10A, it was confirmed that the conventional graphite-containing layer had a surface roughness (RMS) of 3.46 nm, measured before the surface treatment of the graphite-containing layer and after removing the catalyst substrate. In some example embodiments, ALD deposition may be difficult.

Referring to FIG. 10B, it is confirmed that surface roughness (RMS) of the treatment layer 111 measured after removing the catalyst substrate after the surface treatment 150 of the graphite-containing layer 110 is 5.66 nm. In some example embodiments, ALD deposition may be difficult.

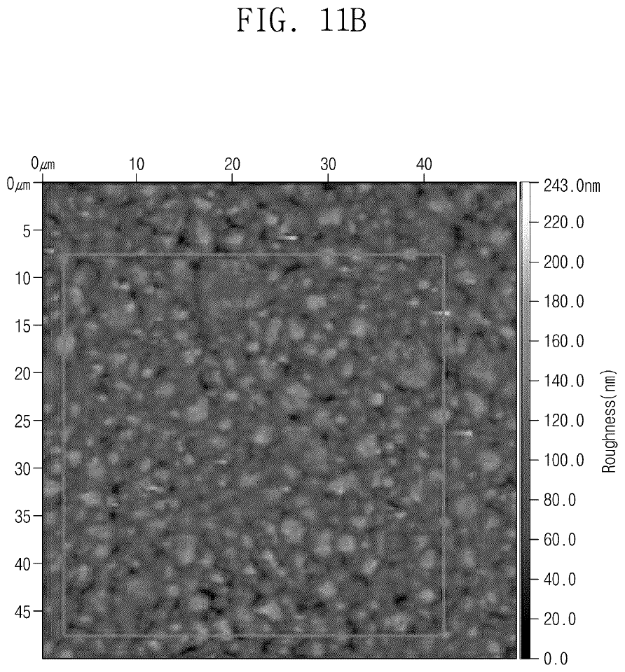

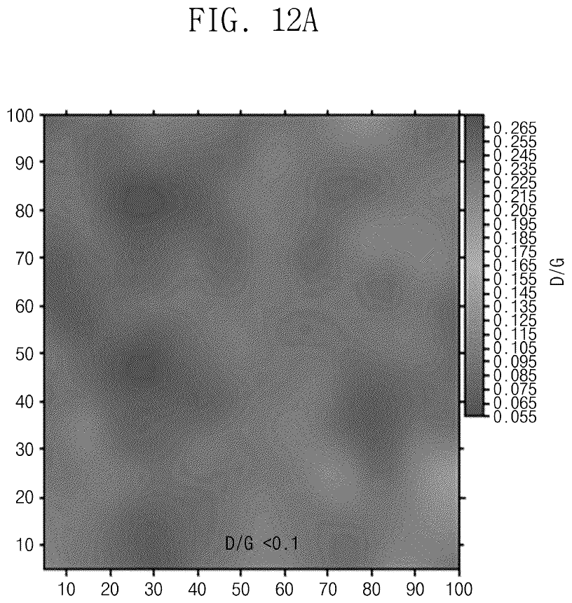

FIGS. 11A and 11B are AFM images for illustrating a conventional graphite-containing layer and a treatment layer, respectively, according to some example embodiments.

Referring to FIG. 11A, it is confirmed that the conventional graphite-containing layer has a surface roughness (RMS) of 32.2 nm, measured when the catalyst substrate is not removed before the conventional graphite-containing layer is surface-treated. In some example embodiments, ALD deposition may be difficult.

Referring to FIG. 11B, it is confirmed that surface roughness (RMS) of the treatment layer 111 has 25.8 nm, measured when the surface treatment 150 of the graphite-containing layer 110 is performed, after the catalyst substrate is removed. In some example embodiments, ALD deposition may be easy.

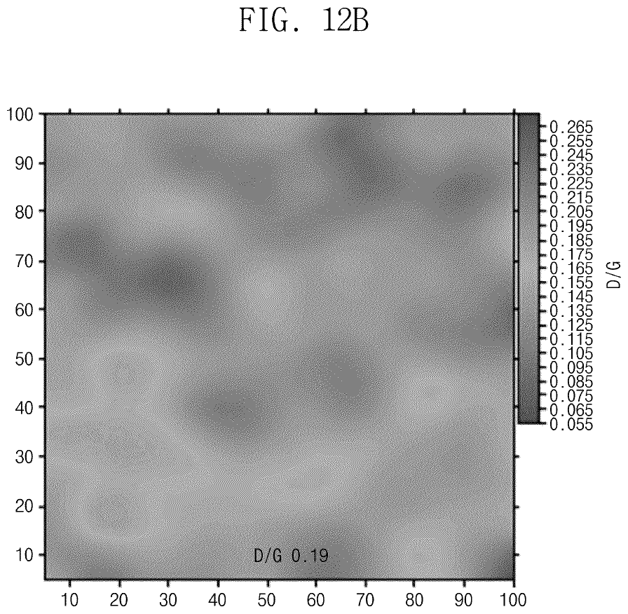

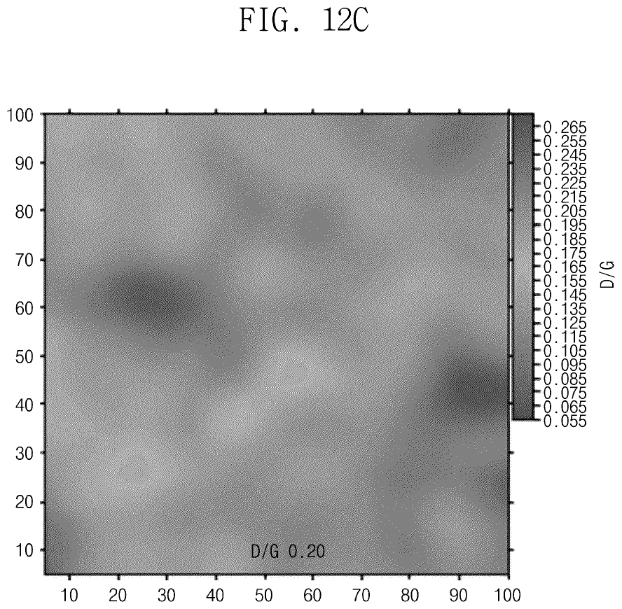

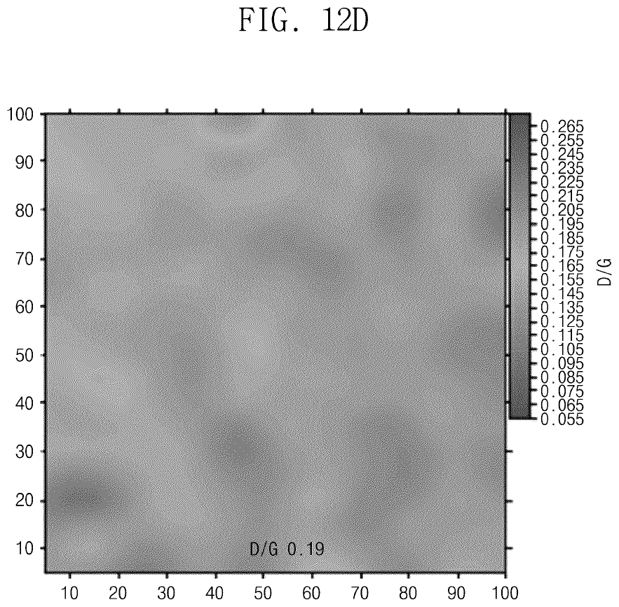

FIGS. 12A, 12B, 12C, and 12D are images for illustrating D/G values of a conventional graphite-containing layer and a treatment layer according to some example embodiments.

Referring to FIG. 12A, a D/G value of the conventional graphite-containing layer is measured to be less than 0.1.

FIGS. 12B to 12D, D/G values of the treatment layer 111 were measured to be 0.1 or more and less than 0.2.

In the pellicle for the extreme ultraviolet exposure according to some example embodiments of the inventive concepts, the treatment layer may be formed through the surface treatment on the graphite-containing layer and thus the passivation layer may be more easily deposited.

While some example embodiments are described above, a person skilled in the art may understand that many modifications and variations are made without departing from the spirit and scope of the inventive concepts defined in the following claims. Accordingly, the example embodiments of the inventive concepts should be considered in all respects as illustrative and not restrictive, with the spirit and scope of the inventive concepts being indicated by the appended claims.

What is claimed is:

1. A method of manufacturing a pellicle for an extreme ultraviolet exposure, the method comprising:
forming a graphite-containing layer on a catalyst substrate;
surface-treating a first surface of the graphite-containing layer to form a first treatment layer; and
forming a first passivation layer on the first treatment layer,
wherein the forming of the first treatment layer includes removing a C—O—C bond included in the graphite-containing layer through the surface-treating of the first surface.

2. The method of claim 1, wherein the forming of the first treatment layer includes generating at least one of a C═O bond, a C—OH bond, or an O═C—OH bond through the surface-treating of the first surface.

3. The method of claim 1, wherein the forming of the first treatment layer includes exposing the first surface of the graphite-containing layer to an oxygen plasma.

4. The method of claim 1, wherein the first passivation layer is formed through atomic layer deposition (ALD).

5. The method of claim 1, wherein the forming of the first treatment layer includes forming the first treatment layer such that a surface roughness (RMS) of the first treatment layer is greater than 3.46 nm and less than 32.3 nm.

6. The method of claim 1, wherein the forming of the first treatment layer includes forming the first treatment layer such that a D/G ratio of the first treatment layer is 0.1 or more and less than 0.2.

7. The method of claim 1, further comprising:
surface-treating a second surface of the graphite-containing layer to form a second treatment layer; and
forming a second passivation layer on the second treatment layer.

8. The method of claim 7, wherein the second treatment layer and the second passivation layer are formed subsequently to covering the first passivation layer with a sublimation material.

9. The method of claim 1, wherein the forming of the first passivation layer includes forming the first passivation layer to include at least one of TiN, BC, BN, SiC, Zr, or Mo.

10. A method of manufacturing a pellicle for an extreme ultraviolet exposure, the method comprising:
forming a graphite-containing layer on a catalyst substrate;
surface-treating a first surface of the graphite-containing layer to form a first treatment layer; and
forming a first passivation layer on the first treatment layer,
wherein the forming of the first treatment layer includes generating at least one of a C═O bond, a C—OH bond, or an O═C—OH bond through the surface-treating of the first surface.

11. The method of claim 10, wherein the forming of the first treatment layer includes removing a C—O—C bond included in the graphite-containing layer through the surface-treating of the first surface.

12. The method of claim 10, wherein, through the surface-treating of the first surface, the first treatment layer has a greater radical adsorption than a radical adsorption of the graphite-containing layer.

13. The method of claim 10, further comprising:
surface-treating a second surface of the graphite-containing layer to form a second treatment layer; and
forming a second passivation layer on the second treatment layer.

14. The method of claim 13, wherein the forming of the second passivation layer includes forming the second passivation layer to include a material different from a material of the first passivation layer.

15. The method of claim 10, wherein the forming of the first passivation layer includes forming the first passivation layer such that the first passivation layer has a thickness of less than 3 nm and greater than 0.01 nm.

16. The method of claim 10, wherein the forming of the first treatment layer includes exposing the first surface of the graphite-containing layer to an oxygen plasma.

17. The method of claim 16, wherein the exposing of the first surface to the oxygen plasma includes exposing the first surface to 50 sccm of oxygen gas at 101V for 30 seconds to 1 minute and 30 seconds.

18. The method of claim 10, wherein the forming of the first treatment layer includes forming the first treatment layer such that a surface roughness (RMS) of the first treatment layer is greater than 3.46 nm and less than 32.3 nm.

19. The method of claim 13, wherein the forming of the second passivation layer includes forming the second passivation layer to include at least one of TiN, BC, BN, SiC, Zr, or Mo.

20. A pellicle for an extreme ultraviolet exposure, the pellicle comprising:
a graphite-containing layer;
a first treatment layer on the graphite-containing layer; and
a first passivation layer on the first treatment layer,
wherein the first passivation layer includes element “X”,
wherein the first treatment layer is connected to the first passivation layer by a C—O—X bond, and
wherein the element “X” includes at least one of Ti, B, Si, Zr, or Mo.
